(19) United States
(12) Patent Application Publication
(10) Pub. No.: US 2010/0116645 A1
(43) Pub. Date: May 13, 2010

(54) SURFACE PROCESSING METHOD AND MANUFACTURING METHOD OF RECORDING MEDIUM

(75) Inventors: Yoichi Sato, Higashine (JP); Shigeru Horigome, Higashine (JP); Satoshi Takiguchi, Higashine (JP); Yasutake Takamatsu, Higashine (JP); Katsunori Takahashi, Higashine (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Minato-ku, Tokyo (JP)

(21) Appl. No.: 12/593,250

(22) PCT Filed: Mar. 27, 2007
(86) PCT No.: PCT/JP2007/056396

§ 371 Date: Sep. 25, 2009

(51) Int. Cl. C23C 14/40

(52) U.S. Cl. 204/192.13

(57) ABSTRACT

A surface processing method of processing a surface of a substrate includes disposing the substrate in a vacuum chamber, processing by applying a high-frequency voltage to the substrate and by sputtering the surface of the substrate, measuring a cathode drop potential generated at the substrate in the processing and obtaining a time integration value of the cathode drop potential, and determining whether or not a processed state of the surface of the substrate is good based on the time integration value obtained in the measuring.

### TECHNICAL FIELD

The present invention relates to a surface processing method of processing a surface of a substrate and a manufacturing method of a recording medium.

### BACKGROUND ART

As the information-oriented society develops, the amount of information continues to increase steadily. To cope with this increase in the amount of information, the development of an information recording scheme and information storage device for achieving a remarkably high recording density has been eagerly awaited. In particular, magnetic disks in which information access is performed in a magnetic field have gained much attention as a high-density recording medium capable of rewriting information, and active research and development efforts are being made to achieve still higher recording densities, etc.

A magnetic disk, in general, has a structure in which a under layer to be a base layer, and a magnetic layer for recording information are successively laminated on a substrate and, further on top of the magnetic layer, a protection layer made up of, for example, DLC (Diamond Like Carbon) is formed. As a magnetic disk device which may access information at a high recording density to and from a magnetic disk, magnetic disk devices of a floating-head type, in which a magnetic head for generating a magnetic field is floated by an air flow produced by the rotation of the magnetic disk, are widely used. There is a risk with a floating-head type magnetic disk device that, in order to efficiently apply a magnetic field to the magnetic disk device, the distance between the magnetic disk and the magnetic head is very small and, for example, when the magnetic disk device is subjected to an impact while the magnetic head is floated, the magnetic head may collide with the magnetic disk to cause the protection layer to peel off thereby destroying the information recorded in the magnetic layer of the magnetic disk. In order to solve such a problem, an attempt is made to laminate a lubricant layer further on top of the protection layer of the magnetic disk to reduce the friction of the surface of the magnetic disk so that upon collision, the magnetic head slides on the surface of the magnetic disk. This lubricant layer also serves to prevent the adherence of moisture and a foreign matter, etc. onto the surface of the magnetic disk, as well as to improve the wear resistance of the magnetic disk and the magnetic head.

However, while the magnetic disk is in operation, the interior of the magnetic disk device is generally in a state of high temperature, and thereby a problem may arise in that a lubricant layer applied to the surface of the magnetic disk is moved toward a circumferential side because of a centrifugal force resulted from a high-speed revolution and a high temperature, and the lubricant layer eventually peels off from the magnetic disk during repeated uses.

In this respect, Japanese Laid-Open Patent Publication Nos. H06-325357 and 2003-223710 describe a technique to improve the adherence strength of a lubricant layer, by applying a sputtering using an oxygen or nitrogen plasma, etc. on the surface of the protection layer to add a surface functional group onto the protection layer surface and thereafter applying the lubricant layer. Hereafter, an example of the processing method of the protection layer will be described.

First, a magnetic disc with a protection layer being applied thereto is held by a metallic holder, and the magnetic disk is disposed in a metallic chamber in vacuum. Introducing a source gas such as oxygen and nitrogen into the chamber to increase the pressure thereinside, and further applying a high-frequency voltage between the chamber and the magnetic disk, will result in a generation of a plasma of the source gas in the chamber. At this moment, there is generated on the surface of the magnetic disk, a cathode drop potential of a magnitude responsive to the high-frequency voltage applied to the magnetic disk, and ions in the plasma are accelerated by the cathode drop potential to collide with the magnetic disk surface. As a result, a sputtering by ions and a chemical change of the source gas simultaneously take place, and the protection layer of the magnetic disc surface is oxidized and nitrided resulting in a surface functional group being added to the protection layer.

In this occasion, although it is ideal that the cathode drop potential generated on the surface of the magnetic disk is entirely utilized for the sputtering treatment, in reality, the cathode drop potential is partly returned as a reflected wave. Since the magnitude of the reflected wave will change depending on the contact area between the holder and the magnetic disk, stains in the metallic chamber, the impedance of the holder, and the like, when processing the surface of the magnetic disk, it is practiced to measure the cathode drop potential and the reflected wave thereby determining the processed state of the surface of the magnetic disk.

FIG. 1 is a graph to illustrate an example of cathode drop potential and reflected wave.

In FIG. 1, the lateral axis indicates time, the longitudinal axis of the upper graph g1_1 indicates the magnitude of cathode drop potential, and the longitudinal axis of the lower graph g2_1 indicates the magnitude of reflected wave.

Upon determination of the processed state of the surface of the magnetic disk, the magnitudes of a cathode drop potential V_t₀ and a reflected wave R_t₀ at a time when a time period t₀ in which the cathode drop potential is empirically considered to be sufficiently stabilized has elapsed since a high-frequency voltage is applied between the holder and the chamber are respectively measured. If the cathode drop potential V_t₀ is not less than a predetermined threshold V₀ and the reflected wave R_t₀ is less than a predetermined threshold R₀, it is inferred that the cathode drop potential has been sufficiently generated and further, sputtering processing is performed with a small amount of reflected wave, leading to a determination that the processed state of the surface of the magnetic disk is good. Further, if the cathode drop potential V_t₀ is less than the threshold V₀ or the reflected wave R_t₀ is not less than the threshold R₀, it is considered that the cathode drop potential is not sufficiently generated or the reflected wave is large so that the cathode drop potential has not been sufficiently utilized for sputtering treatment, leading to a determination that the processed state of the surface of the magnetic disk is not good. In the example illustrated in FIG. 1, since at a time when a time period t₀ has elapsed, the cathode drop potential V_t₀ exceeds the threshold V₀ and further the reflected wave R_t₀ is less than the threshold R₀, it is determined that the processed state of the surface of the magnetic disk is good.

### DISCLOSURE OF INVENTION

Here, in general, a reflected wave is likely to be generated in the interval before cathode drop potential is stabilized; however, when abnormal discharge takes place because of the stains of the chamber, poor contact between the magnetic disk and the holder, and the like, the reflected wave is likely to continue to be generated even after the cathode drop potential is stabilized. For this reason, even if the reflected wave temporarily subsides at a time t₀, a large reflected wave may be generated thereafter leading to a risk that the surface of the magnetic disk may not be sufficiently processed.

FIG. 2 is a graph to illustrate an example of cathode drop potential and reflected wave.

In FIG. 2 as well, the lateral axis indicates time, and the longitudinal axis of the upper graph g1_2 indicates the magnitude of the cathode drop potential and the longitudinal axis of the lower graph g2_2 indicates the magnitude of the reflected wave.

In the example illustrated in FIG. 2, since the cathode drop potential V_t₀ exceeds the threshold V₀ at a time when a time period t₀ has elapsed, and further the reflected wave R_t₀ is less than the threshold R₀, according to the above described determination, the processed state of the surface of the magnetic disk will be good; however, in reality, a large reflected wave takes place after the time t₀, and part of the cathode drop potential is not utilized for sputtering treatment and the surface processing is insufficient. Thus, conventional techniques have a problem that the determination accuracy of the processed state is low.

Further, such problem is not limited to magnetic disks, but may arise in general in the fields where a surface processing method of applying a high-frequency voltage to a substrate and sputtering the surface of the substrate is utilized.

In view of the foregoing, it is an object in one aspect of the invention to provide a method of surface processing and a method of manufacturing a recording medium, in which it is possible to accurately determine a processed state of a substrate.

According to an aspect of the invention, a surface processing method of processing a surface of a substrate, includes:

disposing the substrate in a vacuum chamber;

processing by applying a high-frequency voltage to the substrate and by sputtering the surface of the substrate;

measuring a cathode drop potential generated at the substrate in the processing and obtaining a time integration value of the cathode drop potential, and

determining whether or not a processed state of the surface of the substrate is good based on the time integration value obtained in the measuring.

It is noted that while a cathode drop potential has a negative value since it indicates a fall from a reference potential, and the time integration value of the cathode drop potential also has a negative value, “the time integration value of cathode drop potential” referred to in the present invention indicates the absolute value with the sign removed.

Applying a high-frequency voltage to a substrate causes a cathode drop potential to be generated on the surface of the substrate, and by the cathode drop potential, the surface of the substrate is processed by sputtering. However, in general, the generated cathode drop potential is not entirely utilized for sputtering, but is partly returned as a reflected wave. Conventionally, in a surface processing treatment for processing the surface of a substrate, when the cathode drop potential is sufficiently generated and the reflected wave is small at a time when a predetermined time has elapsed since a high-frequency voltage is applied, it is determined that the processed state of the surface of the substrate is good. As a result of this, when a large reflected wave is generated or the generation amount of cathode drop potential has decreased after a further time has elapsed, a problem arises in that defective products in which the substrate is not sufficiently processed are mixed in normal products.

As a result of analyzing such a problem, it is confirmed that there is a good correlation between the time integration value of the cathode drop potential and the processing amount of the surface of the substrate. In the surface processing method of the present invention, utilizing such analysis result, a time integration value of a cathode drop potential, which is generated by the application of a high-frequency voltage to the substrate, is measured and based on the time integration value thereof, the processed state of the surface of the substrate is determined. For this reason, even when a large reflected wave is generated or the generation amount of the cathode drop potential has decreased while the surface of the substrate is processed, it is possible to accurately determine the processed state of the surface of the substrate.

In addition, in the surface processing method according the one aspect of the invention, it is preferable that the surface processing method according to claim 1, further includes:

instructing a stop of the applying of the high-frequency voltage to the substrate, wherein

the processing is stopping the applying of the high-frequency voltage to the substrate upon receipt of the instruction of the stop the applying of the high-frequency voltage to the instructing, and

the measuring is obtaining a time integration value of the cathode drop potential generated in an interval from when the high-frequency voltage is applied to the substrate to when the applying of the high-frequency voltage is stopped.

According to this preferred surface processing method, by instructing the stop of the application of high-frequency voltage, it is possible to control the amount of high-frequency voltage applied to the substrate, and to adjust the processing amount of the surface of the substrate.

In addition, in the surface processing method, it is preferable that the determining is determining that the processed state of the surface of the substrate is good if the time integration value is not less than a predetermined first threshold value.

It is confirmed that there is a good correlation between the time integration value of cathode drop potential and the processing amount of the surface of a substrate, and by using whether or not the time integration value is not less than a first threshold value determination criterion, it is possible to accurately determine the processed state of the surface of the substrate.

In addition, in the surface processing method according to the invention, it is preferable that the surface processing method further includes introducing a gas into the chamber, wherein the processing is forming a plasma of the gas on the substrate by applying the high-frequency voltage to the substrate, and sputtering the surface of the substrate with an ion in the plasma.

By using a plasma, it is possible to efficiently process the surface of the substrate.

In addition, in the surface processing method according to the invention, it is preferable that the processing is sputtering the surface of the substrate by using a nitrogen plasma or an oxygen plasma.

By utilizing a nitrogen plasma or an oxygen plasma, it is possible to concurrently generate a sputtering by means of ions in the plasma and an oxidation or nitriding treatment.

Further, according to an aspect of the invention, a manufacturing method of a recording medium to record information, includes:

forming, on a substrate, a recording layer to record information, and a protection layer to protect the recording layer;

disposing the substrate in a vacuum chamber;

processing by applying a high-frequency voltage to the substrate and by sputtering the surface of the substrate;

measuring a cathode drop potential generated in the substrate in the processing to acquire a time integration value of the cathode drop potential;

determining whether or not a processed state of the surface of the substrate is good based on the time integration value obtained in the measuring; and

forming a lubricant layer on the protection layer if it is determined that the processed state of the protection layer is good in the determining.

According to the manufacturing method of the recording medium of the one aspect of the present invention, it is possible to accurately determine the processed state of the surface of the substrate on which a recoding layer and a protection layer are formed, and to form a lubricant layer only on a substrate which is in good processed state.

Furthermore, the manufacturing method according to the invention, it is desirable the processing is producing a surface functional group in the protection layer, by sputtering the protection layer.

As a result of a surface functional group being formed on the protection layer, it is possible to improve the adhesive strength between the lubricant layer and the protection layer.

As so far described, according to the present invention, it is possible to provide a surface processing method which enable to accurately determine the processed state of the substrate surface, and a manufacturing method of a recording medium.

### BRIEF DESCRIPTION OF DRAWINGS

FIG. 1 is a graph to illustrate an example of a cathode drop potential and a reflected wave.

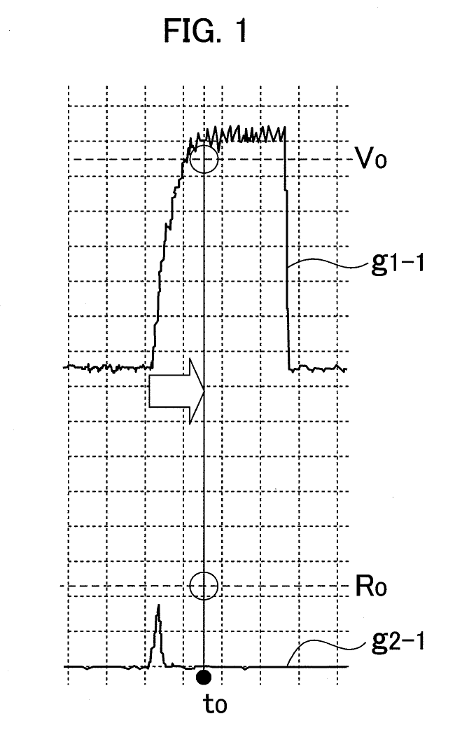

FIG. 2 is a graph to illustrate an example of cathode drop potential and reflected wave.

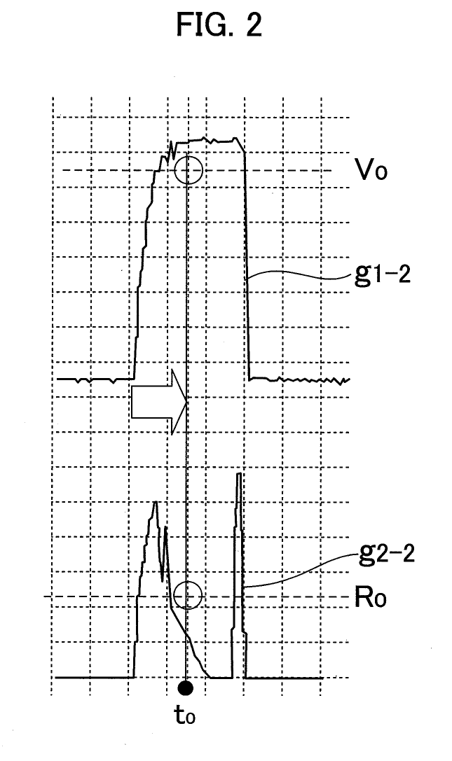

FIG. 3 illustrates a manufacturing method of a magnetic disk to which an embodiment of the present invention is applied.

FIG. 4 illustrates a surface processing apparatus for processing the surface of a magnetic disk.

FIG. 5 illustrates a state of a surface of a magnetic disk when a high-frequency voltage is applied.

FIG. 6 is a graph illustrating a relationship between a time integration value of a cathode drop potential Vdc and a nitriding amount.

FIG. 7 is a graph illustrating examples of the cathode drop potential and the reflected wave.

### BEST MODE FOR CARRYING OUT THE INVENTION

Hereafter, embodiments of the present invention will be described with reference to the drawings.

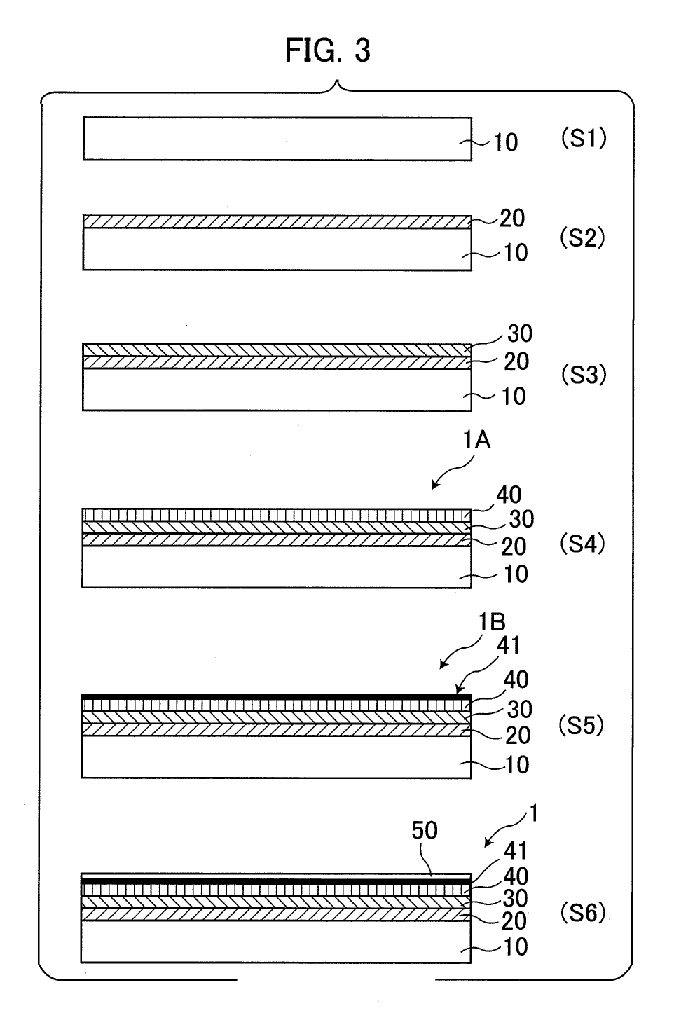

FIG. 3 illustrates a manufacturing method of a magnetic disk to which an embodiment of the present invention is applied.

The present embodiment is a manufacturing method of a magnetic disk for manufacturing magnetic disks which record information using a magnetic field, and FIG. 3 illustrates the layer structure of the magnetic disk in each process.

First, a substrate 10 of a magnetic disk is prepared (step S1 of FIG. 3). As the substrate 10, a nonmagnetic metal material and glass etc. may be applied, and an aluminum substrate is applied in the present embodiment.

Next, a under layer 20 is formed on the substrate 10 (step S2 of FIG. 3). As the under layer 20, a nonmagnetic metal material etc. may be applied, and chromium is formed by sputter deposition in the present embodiment.

When the under layer 20 is formed, a magnetic layer 30 is laminated further thereon (step S3 of FIG. 3). The magnetic layer 30, in the present embodiment, which provides a recording layer for recording information, is formed by sputter deposition of Co—Ni. The magnetic layer 30 corresponds to an example of the recording layer referred to in the present invention.

Further, a protection layer 40 is formed on the magnetic layer 30 (step S4 of FIG. 3). As the protection layer 40, which is for protecting the magnetic layer 30 etc., carbon is laminated by a plasma CVD (Chemical Vaporing Deposition) method. Since the plasma CVD method is a layer deposition method which has been widely used heretofore, detailed description thereof will be omitted herein. The protection layer 40 corresponds to an example of the protection layer referred to in the present invention.

The above described series of treatments from step S1 to step S4 correspond to an example of the forming layers in the manufacturing method of a recording medium of the present invention. Although the magnetic disk 1A, as it is in the present state, may read and write information at this time point, a lubricant layer 50 is further formed on the protection layer 40 of the magnetic disk 1A in order to prevent the adherence of moisture or a foreign matter to the surface of the magnetic disk and to improve the wear resistance of the magnetic disk. In the present embodiment, before the lubricant layer 50 is formed, the protection layer 40 is subjected to a surface processing treatment to add a surface functional group 41 thereby increasing the bonding strength of the lubricant layer 50 (step S5 of FIG. 3).

Now, temporarily, description of FIG. 3 will be interrupted and the surface processing treatment in step S5 of FIG. 3 will be described in detail.

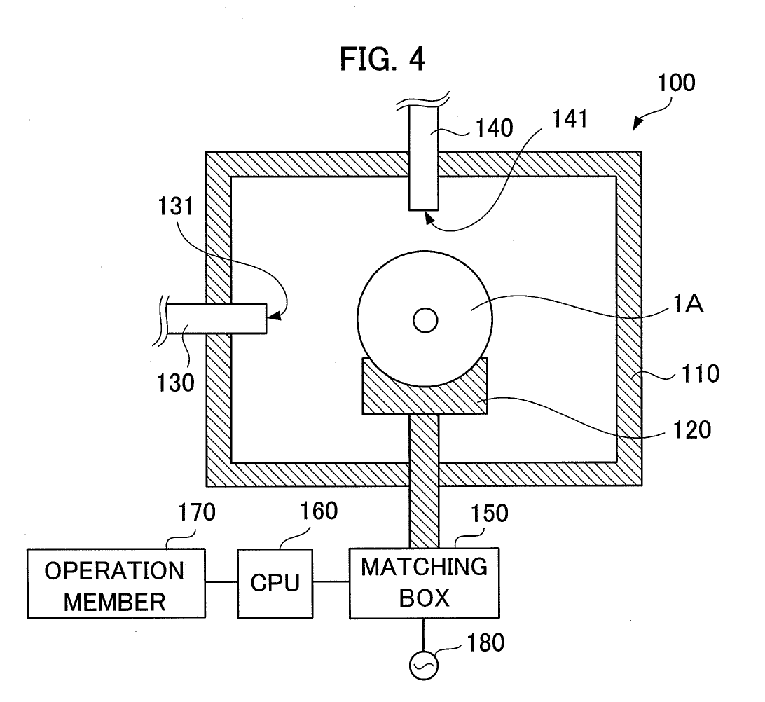

FIG. 4 illustrates a surface processing apparatus for processing the surface of a magnetic disk.

A surface processing apparatus 100 includes a metallic chamber 110, a gas inlet tube 130 for introducing a gas from a gas inlet port 131, a gas outlet tube 140 for discharging a gas from a gas outlet port 141, a metallic holder 120 that holds the magnetic disk, a high-frequency power supply 180 that applies a high-frequency voltage, a matching box 150 that adjusts the impedance of the high-frequency voltage, a CPU 160 that controls the entire surface processing apparatus 100, an operation member 170 for inputting various instructions, and the like. The chamber 110 and the holder 120 are made up of a metal having conductivity and also serve as electrodes.

First, a magnetic disk 1A, which is formed with a protection layer 40 in step S4 of FIG. 3, is disposed in the chamber 110 in vacuum. This process of disposing the magnetic disk 1A corresponds to an example of the disposing referred to in the present invention.

Next, a source gas which provides the raw material for plasma is introduced into the chamber 110 from the gas inlet tube 130 and part of the source gas is discharged from the gas outlet tube 140 so that the interior of the chamber 110 becomes a predetermined pressure. In the present embodiment, nitrogen gas is applied as the source gas. This process of introducing nitrogen gas corresponds to an example of the introducing gas referred to in the present invention.

Next, a high-frequency voltage is applied to the magnetic disk 1A with the chamber 110 and the holder 120 as the electrodes.

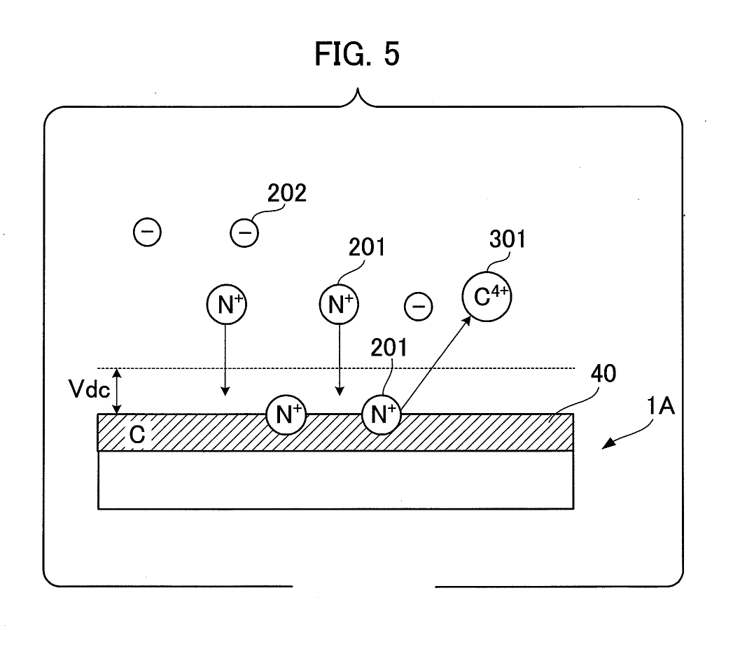

FIG. 5 illustrates the state of the surface of the magnetic disk 1A when a high-frequency voltage is applied.

The high-frequency voltage supplied from the high-frequency power supply 180 is applied to the chamber 110 and the holder 120, which work as the electrodes, after the impedance is matched by the matching box 150. Since, in the present embodiment, the magnetic disk 1A held by the holder 120 is formed on its surface with a carbon-based protection layer 40 having conductivity, the high-frequency voltage applied to the holder 120 is directly conducted to the surface of the magnetic disk 1A. As a result, the chamber 110 works as an anode and the magnetic disk 1A works as a cathode, causing a cathode drop potential Vdc to be generated at the surface of the magnetic disk 1A.

Further, as a result of the high-frequency voltage being applied to the magnetic disk 1A, with the nitrogen gas in the chamber 110 provided as the raw material, a nitrogen plasma, in which nitrogen ions 201 and electrons 202 coexist, is generated. Further, nitrogen ions 210 are attracted by the cathode drop potential Vdc generated at the surface of the magnetic disk 1A to collide with the protection layer 40 of the magnetic disk 1A thereby being partly replaced with carbon ions 301 that form the protection layer 40.

In this way, the carbon making up the protection layer 40 at the surface of the magnetic disk 1A is replaced with nitrogen, and the protection layer 40 is subjected to a nitriding treatment to be added with a surface functional group 41. When the user instructs the end of treatment using the operation member 170, the application of high-frequency voltage from the high-frequency power supply 180 is stopped thereby terminating the nitriding treatment. This process of sputtering the surface of the magnetic disc 1A corresponds to an example of the processing referred to in the present invention.

Here, the amount of the surface functional group 41 that is added through the nitriding treatment of the protection layer 40 of the magnetic disk 1A is controlled by the amount of the source gas and the cathode drop potential Vdc, and the generation amount of cathode drop potential Vdc may be adjusted by the high-frequency voltage applied to the magnetic disk 1A and the application time of the high-frequency voltage. However, the generated cathode drop potential Vdc is not entirely utilized for the nitriding treatment of the magnetic disk 1A, but is partly returned as a reflected wave. Since the amount of such reflected wave will change depending on a dirt level of the chamber 101, the impedance of the holder 120, the contact area between the magnetic disk 1A and the holder 120, and the like, the surface of the magnetic disk may not be sufficiently processed even when a cathode drop potential Vdc is generated by sufficiently applying high-frequency voltage to the magnetic disk 1A. In the present embodiment, determination of whether or not the processed state is good is made for the magnetic disk 1B after being subjected to the nitriding treatment.

In the matching box 150 illustrated in FIG. 4, while the high-frequency voltage is applied from the high-frequency power supply 180, a cathode drop potential Vdc being generated at the surface of the magnetic disk 1A is measured. In the present embodiment, the cathode drop potential Vdc is calculated according to the high-frequency voltage which is applied to the magnetic disk 1A from the high-frequency power supply 180, and the Langmuir-Child equation. The calculated cathode drop potential Vdc is notified to the CPU 160.

In the CPU 160, the time integration value of the cathode drop potential Vdc, which is notified from the matching box 150, is calculated. The process of measuring the cathode drop potential and calculating the time integration value of the cathode drop potential corresponds to an example of the measuring referred to in the present invention.

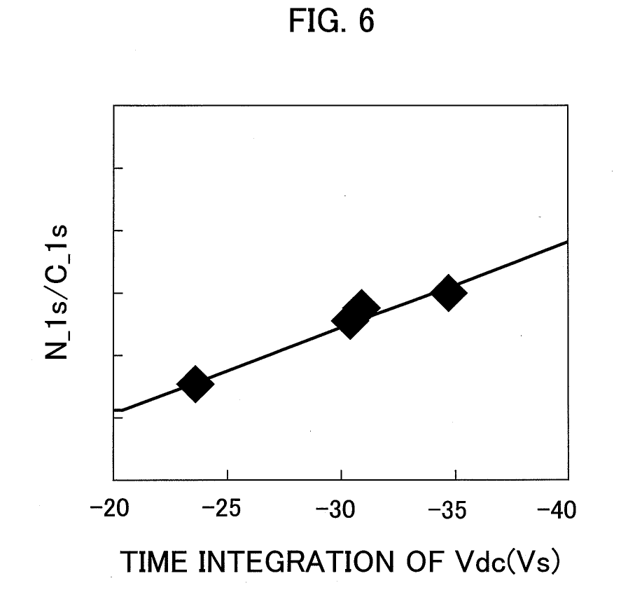

FIG. 6 is a graph to illustrate the relationship between the time integration value of the cathode drop potential Vdc and the nitriding amount at the surface of the magnetic disk 1A.

The lateral axis of FIG. 6 indicates the time integration value (Vs) of the cathode drop potential Vdc, and the longitudinal axis of FIG. 6 indicates the nitriding amount of the surface of the magnetic disk 1A. It is noted that in order to confirm the composition of the protection layer 40 of the magnetic disk 1A, an electron spectroscopy spectrum is measured to obtain a peak strength at the binding energy level of carbon (C_{—}1s: 284 eV) and a peak strength at the binding energy level of nitrogen (N_{—}1s: 399 eV) in the spectrum, and the ratio of the peak levels is calculated as the nitriding amount of the magnetic disk 1A. As illustrated in FIG. 6, there is a good correlation between the time integration of the cathode drop potential Vdc and the nitriding amount of the magnetic disk 1A.

In the CPU 160 illustrated in FIG. 4, the time integration value of the cathode drop potential Vdc in the interval from when a high-frequency voltage is applied to the magnetic disk 1A to when the application of the high-frequency voltage is stopped is calculated; and if the calculated time integration value is not less than a predetermined reference value V₀, it is determined that the processed state of the surface of the magnetic disk 1A is good, and if the absolute value of the time integration value is less than the reference value V₀, it is determined that the processed state of the surface of the magnetic disk 1A is not good. It is noted that although since the cathode drop potential Vdc has a negative value, the time integration value of the cathode drop potential Vdc also has a negative value, in the present embodiment, the determination is made based on the absolute value of the time integration value of the cathode drop potential Vdc. That is, in the CPU 160, determination is made on whether or not the absolute value of the calculated time integration value of the cathode drop potential Vdc is not less than the absolute value of the reference value V₀ (in the present embodiment, V₀=−34.0 Vs). This process of determining the processed state of the surface of the magnetic disk 1A corresponds to an example of the determining referred to in the present invention.

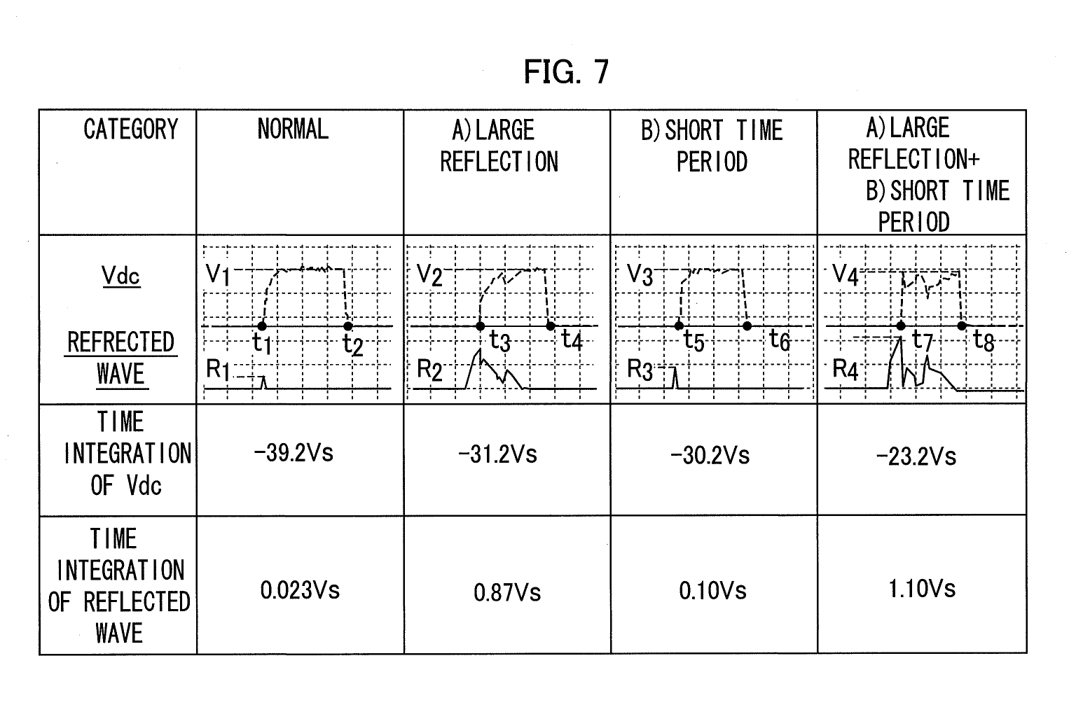

FIG. 7 is a graph to illustrate an example of the cathode drop potential and the reflected wave.

In the four graphs in the upper side of FIG. 7, the lateral axis indicates time and the longitudinal axis indicates cathode drop potential, and in the four graphs in the lower side, the lateral axis indicates time and the longitudinal axis indicates reflected wave.

In the graph V₁ of the cathode drop potential illustrated in the left side of FIG. 7, it is seen that between a time t₁ when a high-frequency voltage is applied, and a time t₂ when the high-frequency voltage is stopped, a stable and sufficient cathode drop potential is generated, and in the graph R₁ of reflected wave, it is seen that the reflected wave is small. In this case, since the time integration value of the generated cathode drop potential is −39.2 Vs, and the absolute value thereof is larger than the absolute value of the reference value V₀=−34.0 Vs, it is determined that the processed state of the surface of the magnetic disk 1A is good.

In the graph V₂ of the cathode drop potential illustrated in the second from left in FIG. 7, it is seen that it takes some time from when a high-frequency voltage is applied to when the cathode drop potential is stabilized, and in the graph R₂ of the reflected wave, it is seen that the reflected wave is large. Since the time integration value of the generated cathode drop potential in graph V₂ is −31.2 Vs and thus the absolute value thereof is smaller than the absolute value of the reference value V₀=−34.0 Vs, it is determined that the processed state of the surface of the magnetic disk 1A is not good. In this case, since the reflected wave is large, it is considered that nitriding treatment has not been sufficiently performed.

In the graph v₃ of the cathode drop potential illustrated in the second from right in FIG. 7, it is seen that the time period between a time t₅ when a high-frequency voltage is applied and a time t₆ when the high-frequency voltage is stopped is small, and the generation time of the cathode drop potential is small; and in the graph R₃ of the reflected wave, it is seen that the reflected wave is small. Since the time integration value of the generated cathode drop potential in graph V₃ is −30.2 Vs and thus the absolute value thereof is smaller than the absolute value of the reference value V₀=−34.0 Vs, it is determined that the processed state of the surface of the magnetic disk 1A is not good. In this case, since the generation time of the cathode drop potential is too short, it is considered that the nitriding treatment has not been sufficiently performed.

In the graph V₄ of the cathode drop potential illustrated in the right side in FIG. 7, it is seen that the cathode drop potential is not stabilized; and in the graph R₄ of the reflected wave, it is seen that the reflected wave is large. Since the time integration value of the generated cathode drop potential in the graph v₄ is −23.2 Vs, and the absolute value thereof is smaller than the absolute value of the reference value V₀=−34.0 Vs, it is determined that the processed state of the surface of the magnetic disk 1A is not good. In this case, since the reflected wave is large and the generation time of the cathode drop potential is too small, it is considered that nitriding treatment has not been sufficiently performed.

In this way, according to the present embodiment, it is possible to accurately determine the processed state of the surface of the magnetic disk 1A.

Now, description will be made returning to FIG. 3.

When nitriding treatment is applied to the protection layer 40 of the magnetic disk 1A, the surface functional group 41 is formed on the surface of the magnetic disk 1A (step S5 of FIG. 3). In the CPU 160 illustrated in FIG. 4, the processed state of the surface functional group 41 of the magnetic disk 1A is determined, and only the magnetic disks 1B which are determined that the surface functional group 41 is sufficiently formed (the processed state is good) are passed to the next lubricant application process.

The magnetic disk 1B which has been passed over to the lubricant application process is applied with a lubricant on the surface functional group 41 formed on the surface of the magnetic disk 1B and is formed with a lubricant layer 50 (step S5 in FIG. 3). In the present embodiment, a fluorine-containing organic compound is applied as the lubricant layer 50. The process of forming the lubricant layer 50 corresponds to an example of the forming a lubricant layer referred to in the present invention.

Since in the magnetic disk 1, which has been fabricated through the processes as described above, the lubricant layer 50 is strongly adhered to the protection layer 40 by the surface functional group 41, the peeling off of the lubricant layer 50 is prevented, and it is possible to mitigate the adherence of unwanted matters to the surface of the magnetic disk 1 and the wear of the magnetic disk 1 for a long period of time.

So far, the description of the first embodiment of the present invention has been completed and a second embodiment of the present invention will be described. Since the second embodiment of the present invention is subjected to generally similar treatments as in the first embodiment excepting that the surface processing treatment is performed by using an oxygen plasma, only the differences from the first embodiment will be described.

In the manufacturing method of the magnetic disk of the present embodiment, by introducing an oxygen gas into the chamber 110 illustrated in FIG. 4 from the gas inlet tube 130 to generate an oxygen plasma, oxidation treatment is applied to the protection layer 40 of the magnetic disk 1A. Oxidizing a carbon-based protection layer 40 by using an oxygen plasma will result in the formation of surface functional group 41 such as ether (C—O—C), carbonyl (C═O), peroxide (C—O—OH), and the like on the surface of the protection layer 40, making it possible to improve the adsorptivity of the lubricant layer 50 particularly made up of a fluorine-containing organic compound etc.

Although, so far in the above description, an example of determining the processed state of the surface of the magnetic disk by using the time integration value of cathode drop potential has been described, the determining referred to in the present invention may determine the processed state by using the time integration value of reflected wave in addition to the time integration value of cathode drop potential.

Further, although in the above description, an example of processing the surface of a magnetic disk has been described, the surface processing method of the present invention may be applied to the surface processing of, for example, CD-ROM, etc.

Furthermore, although in the above description, an example of performing sputtering treatment by using a plasma has been described, the processing referred to in the present invention may perform sputtering treatment by using a target.

Further, although in the above description, an example of applying a high-frequency voltage to the magnetic disk until the user give the instructions to stop the application of the high-frequency voltage has been described, the processing referred to in the present invention may apply a high-frequency voltage to the substrate for a predetermined time period.

What is claimed is:

1. A surface processing method of processing a surface of a substrate, comprising:
disposing the substrate in a vacuum chamber;
processing by applying a high-frequency voltage to the substrate and by sputtering the surface of the substrate;
measuring a cathode drop potential generated at the substrate in the processing and obtaining a time integration value of the cathode drop potential, and
determining whether or not a processed state of the surface of the substrate is good based on the time integration value obtained in the measuring.

2. The surface processing method according to claim 1, further comprising:
instructing a stop of the applying of the high-frequency voltage to the substrate, wherein
the processing is stopping the applying of the high-frequency voltage to the substrate upon receipt of the instruction of the stop the applying of the high-frequency voltage to the instructing, and
the measuring is obtaining a time integration value of the cathode drop potential generated in an interval from when the high-frequency voltage is applied to the substrate to when the applying of the high-frequency voltage is stopped.

3. The surface processing method according to claim 1, wherein
the determining is determining that the processed state of the surface of the substrate is good if the time integration value is not less than a predetermined first threshold value.

4. The surface processing method according to claim 1, further comprising:
introducing a gas into the chamber, wherein
the processing is forming a plasma of the gas on the substrate by applying the high-frequency voltage to the substrate, and sputtering the surface of the substrate with an ion in the plasma.

5. The surface processing method according to claim 1, wherein
the processing is sputtering the surface of the substrate by using a nitrogen plasma or an oxygen plasma.

6. A manufacturing method of a recording medium to record information, comprising:
forming, on a substrate, a recording layer to record information, and a protection layer to protect the recording layer;
disposing the substrate in a vacuum chamber;
processing by applying a high-frequency voltage to the substrate and by sputtering the surface of the substrate;
measuring a cathode drop potential generated in the substrate in the processing to acquire a time integration value of the cathode drop potential;
determining whether or not a processed state of the surface of the substrate is good based on the time integration value obtained in the measuring; and
forming a lubricant layer on the protection layer if it is determined that the processed state of the protection layer is good in the determining.

7. The manufacturing method according to claim 6, wherein
the processing is producing a surface functional group in the protection layer by sputtering the protection layer.
